(19) United States
(12) Patent Application Publication
(10) Pub. No.: US 2026/0170201 A1
(43) Pub. Date: Jun. 18, 2026

(54) CLOTHING SIMULATION WITH LOCALIZED DEFORMATION AND BLENDING

(71) Applicant: CLO Virtual Fashion Inc., Seoul (KR)

(72) Inventor: Sperl GEORG, Laxenburg (AT)

(21) Appl. No.: 19/533,156

(22) Filed: Feb. 7, 2026

Related U.S. Application Data
(63) Continuation-in-part of application No. PCT/KR2024/011793, filed on Aug. 8, 2024.

(30) Foreign Application Priority Data
Aug. 8, 2023 (KR) 10-2023-0103790
Aug. 7, 2024 (KR) 10-2024-0105641

(51) Int. Cl. G06F 30/23; G06F 30/20; G06T 13/20; G06T 13/40; G06T 19/20

(52) U.S. Cl. CPC G06F 30/23; G06F 30/20; G06T 13/20; G06T 13/40; G06T 19/20

(57) ABSTRACT

Embodiments relate to a clothing simulation that involves selecting one or more points or areas of clothing and determining activation areas affected by motion or displacement of the selected points or areas. The activation areas encompass the selected points or areas and an intermediate area surrounding them. The method receives the motion or displacement of the selected points or areas and simulates the clothing with the selected points or areas deformed accordingly. The intermediate area is deformed to blend the deformation of the selected points or areas with a surrounding simulation area, providing a realistic clothing simulation.

### CROSS-REFERENCE TO RELATED APPLICATIONS

This is a bypass continuation of International PCT Application No. PCT/KR2024/011793, filed on Aug. 8, 2024, which claims priority to Republic of Korea Patent Application No. 10-2023-0103790, filed on Aug. 8, 2023, and Republic of Korea Patent Application No. 10-2024-0105641, filed on Aug. 7, 2024, which are incorporated by reference herein in their entirety.

### TECHNICAL FIELD

The following embodiments relate to simulating clothing, and more specifically to physics-based simulation of clothing.

### BACKGROUND ART

Clothing simulation technology plays a significant role in the 3D graphics field. Clothing simulation technology may be used in various fields, such as the game industry or fashion design. Clothing simulation may allow a user to design clothing or modify the design in a virtual environment and visualize the clothing before production. With the recent advancement of physics-based simulation, realistic motion and deformation of clothing may be more accurately represented. Physics-based simulation may enable a more natural simulation considering gravity, friction, collision, or the like by using the material properties and physical properties of clothing. Accordingly, the user may experience further realistic clothing design and visualization.

### SUMMARY

Embodiments relate to clothing simulation. Selection of one or more points or areas of clothing is received. The motion or the displacement of the one or more selected points or areas is received. One or more activation areas include the one or more selected points or areas, and an intermediate area around the one or more selected points or areas. The selected one or more points or areas are constrained by the received motion or displacement in the one or more physics simulation steps. In the one or more physics simulation steps, the intermediate area is partially constrained according to the received motion or displacement.

In one or more embodiments, the deformation of the one or more selected points or areas is displayed in real-time responsive to receiving the motion or the displacement of the one or more selected points or areas.

In one or more embodiments, the motion includes at least one of rotation, translation, scaling, or twisting.

In one or more embodiments, the one or more activation areas are defined by a distance from the selected points or areas represented in Euclidean distance or geodesic distance.

In one or more embodiments, the one or more activation areas are determined by performing smoothing or weight painting using a bitmap-based brush or stamp.

In one or more embodiments, the one or more activation areas are determined further by normalization of weight values for blending or limiting the activation areas to a specific part of the clothing, a mesh of the clothing, or a pattern of the clothing.

In one or more embodiments, weight values for partially constraining the intermediate area by blending vertex displacements in the physics simulation steps are determined by a function selected by a user.

In one or more embodiments, the function is selected from a predetermined number of preset functions displayed to the user on a graphical user interface.

In one or more embodiments, the blending is performed by interpolation.

In one or more embodiments, weight values for interpolating in the intermediate area are adjusted to a value between 0 and 1 according to a weight function.

In one or more embodiments, the one or more activation areas cover a pattern including the one or more selected points or areas and another pattern adjacent to the pattern.

In one or more embodiments, the one or more activation areas cover a pattern including the one or more selected points or areas and another pattern in a layer different from the pattern.

In one or more embodiments, a pinching interface is displayed. The pinching interface is used for receiving the motion or displacement from a user.

In one or more embodiments, the pinching interface displaces the one or more selected points or areas in a direction corresponding to a user input.

In one or more embodiments, a gizmo interface is displayed. The gizmo interface is used for receiving the motion or displacement from a user.

In one or more embodiments, the one or more activation areas include a portion visually displaying weight values for blending.

In one or more embodiments, the one or more activation areas cover a layer of a pattern when the pattern is multi-layered.

In one or more embodiments, at least a part of one or more regions external to the activation areas is propagated with deformation according to the motion or the displacement in subsequent physics simulation steps after the one or more physics simulation steps.

### BRIEF DESCRIPTION OF DRAWINGS

FIG. 1 is a flowchart illustrating a method of simulating clothing, according to an embodiment.

FIG. 2 is a graphical user interface diagram illustrating a screen area for adjusting the distance of influence, according to an embodiment.

FIGS. 3A and 3B are graphical user interface diagrams illustrating soft selection, according to an embodiment.

FIGS. 4A and 4B are graphical user interface diagrams illustrating deformation of a soft selection activation area according to a falloff distance adjustment, according to an embodiment.

FIGS. 5A through 5E are graphical user interface diagrams illustrating deformation of a soft selection activation area according to a falloff power adjustment, according to an embodiment.

FIGS. 6A through 6E are diagrams illustrating a weight distribution of deformation according to adjustment of a falloff kernel menu, according to an embodiment.

FIG. 7 is a diagram schematically illustrating soft selection activation areas defined by Euclidean distance or geodesic distance, according to embodiments.

FIG. 8 is a graphical user interface diagram schematically illustrating geodesic distance-based soft selection, according to an embodiment.

FIG. 9 is a diagram schematically illustrating multi-soft selection, according to an embodiment.

FIGS. 10A through 10C are graphical user interface diagrams illustrating operations of a gizmo interface, according to an embodiment.

FIG. 11 is a diagram schematically illustrating a pinching interface, according to an embodiment.

FIGS. 12A and 12B are diagrams illustrating the operation of the pinching interface, according to an embodiment.

FIG. 13 is a block diagram illustrating an electronic device according to an embodiment.

### DETAILED DESCRIPTION

The following detailed structural or functional description is provided as an example only, and various alterations and modifications may be made to the examples. Here, examples are not construed as limited to the disclosure and should be understood to include all changes, equivalents, and replacements within the idea and the technical scope of the disclosure.

Terms, such as first, second, and the like, may be used herein to describe various components. Each of these terminologies is not used to define an essence, order or sequence of a corresponding component but used merely to distinguish the corresponding component from other component(s). For example, a first component may be referred to as a second component, and similarly the second component may also be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof.

Unless otherwise defined, all terms, including technical and scientific terms, used herein have the same meaning as commonly understood by one of ordinary skill in the art to which the present disclosure pertains. Terms, such as those defined in commonly used dictionaries, are to be interpreted as having a meaning that is consistent with their meaning in the context of the relevant art and are not to be interpreted in an idealized or overly formal sense unless expressly so defined herein.

Hereinafter, embodiments will be described in detail with reference to the accompanying drawings. When describing the examples with reference to the accompanying drawings, like reference numerals refer to like components and a repeated description related thereto will be omitted.

When clothing is simulated using a physics simulation, the materials and properties of clothing may be expressed more naturally to reflect user input and/or an external force from the environment. For example, a vertex-based physics simulation may deform clothing by translatory motions of certain vertices on its mesh surface according to the materials and properties of the clothing as well as user input or an external force from the environment. As used herein, the term “clothing” or “garment” refers not only to wearable apparel but also includes various fabric-based objects such as gloves, hats, curtains, bedding, and other flexible material items subjected to physics simulation.

However, such physics simulation may lack a user-friendly interface and intuitive manipulation methods. Specifically, when clothing is complex or includes a plurality of patterns, a simulation resulting in a natural appearance may not be readily achieved. To address such issues, embodiments enable soft selection of the clothing simulation method for the purpose of simulation.

Soft selection defines a selected area around a point or an area specified by the user. The selected area may be deformed based on the user's manipulation to exhibit a natural appearance. Soft selection may result in a more intuitive clothing simulation compared to a previous vertex-based clothing simulation while enabling a tight control of a complex deformation in the clothing.

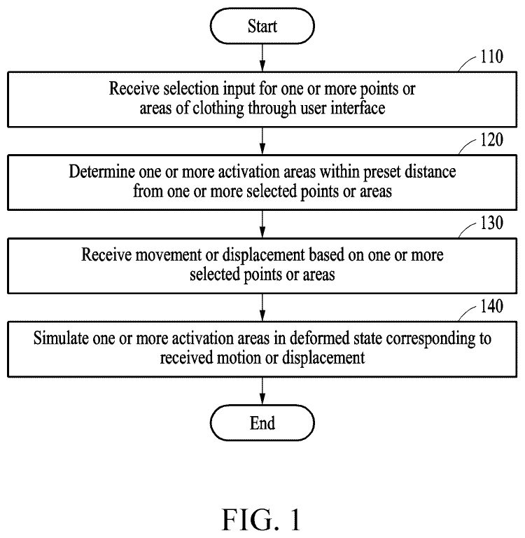

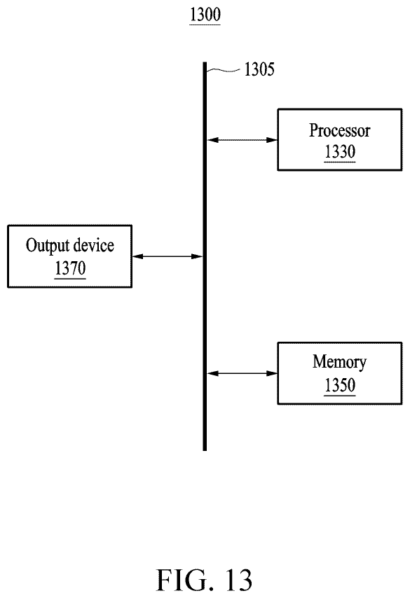

FIG. 1 is a flowchart illustrating a method of simulating clothing, according to an embodiment. Operations 110 to 170 in FIG. 1 may be performed, for example, by using an electronic device 1300 illustrated in FIG. 13. Operations 110 to 170 may also be performed by any other suitable electronic device in a suitable system.

Although FIG. 1 illustrates operations being performed sequentially, the order of some of the operations may be changed or some of the operations may be omitted. For example, some of the operations illustrated in FIG. 1 may be performed in parallel or simultaneously.

In operation 110, the electronic device 1300 receives an input to select one or more points or areas of clothing through a user interface. A user may select a point or an area by touching or clicking on a specific part of the clothing displayed on the user interface by using a touch screen or a mouse cursor. For example, when the user clicks on part of a sleeve of the clothing on a touch screen of the electronic device 1300, one or more points on the sleeve may be selected on the electronic device 1300. Operation 110 may be performed before starting a simulation or after a number of simulation steps has already been performed. The user input for the simulation may be received while a physics-based draping simulation has started, or is in progress. If the user input is received while the draping simulation is in progress, the subsequent operations 120 through 140 may be performed in real-time, enabling the user to interactively and dynamically modify the garment's shape as a continuous physical response.

In operation 120, the electronic device 1300 may determine one or more activation areas within a preset distance from one or more selected points or areas. Any vertices with a maximum weight in these areas act as kinematic constraints or hard constraints within the physics simulation. In one or more embodiments, the selected points or areas may be assigned with the maximum weight values. For such vertices, target positions derived from user input are enforced as boundary conditions prior to resolving a physics integration step. Accordingly, forces computed by the physics solver are propagated from the constrained vertices to other vertices of the clothing mesh.

The preset distance may be defined as either a Euclidean distance or a geodesic distance. The one or more activation areas refer to areas influenced by motion or displacement of a point or an area. The motion may include at least one of rotation, translation, scaling, or twisting. For example, when the user selects part of a sleeve of the clothing, an activation area within a preset distance from the selected point in the sleeve part may be determined automatically.

As used herein, “kinematic constraints” or “hard constraints” refer to boundary conditions where the positions or displacements of specific vertices are pre-determined by user input, thereby overriding the forces calculated by the physics solver for those specific vertices. Any vertices with a maximum weight (e.g., w=1) act as these hard constraints within the physics simulation. These constraints force the physics solver to compute physical updates for the mesh by treating the w=1 vertices as already located at the user-intended position across one or more physics simulation steps. This process results in the solver using the user-intended positions of the constrained vertices as a fixed state for the current integration step, allowing forces to propagate naturally to nearby vertices in both the intermediate blending regions and the external simulation areas.

According to an embodiment, the electronic device 1300 may calculate a weight distribution based on Euclidean distance or geodesic distance. The electronic device 1300 may calculate a weight distribution based on a function received through the user interface. For example, when the user selects a function, such as a linear function, a hat function, a bump function, or a sinusoidal function, using the user interface, the electronic device 1300 may calculate the weight distribution based on the received function.

According to an embodiment, the electronic device 1300 may generate another weight distribution in addition to the weight distribution generated through preset functions as described above. For example, when the user inputs any shape (e.g., a pattern with complex unevenness) desired by the user through the user interface, the electronic device 1300 may calculate the weight distribution by functionalizing the input shape. The electronic device 1300 may calculate the weight distribution based on the preset functions in memory 1350 or by mapping the preset functions like the shape desired by the user. For example, the electronic device 1300 may calculate the weight distribution through a new function by loading, from the memory 1350, and mapping a preset function having a basic form that is similar to a shape (e.g., a shape including many sharp uneven parts outside a circular line) desired by the user and deforming the preset function to fit the shape as intended by the user.

A weight of an activation area indicates the degree to which a selected point or area influences the deformation of the activation area in one or more physics simulation steps based on a received motion or displacement. The weight may be a function of a distance from the activation area to the selected point or area. For example, a numerical value representing the weight of the activation areas as the distances to the activation areas increase from the selected point or area. When the user selects and drags an end of a sleeve through the touch screen to select the sleeve, a part closer to the sleeve end may deform more, and a shoulder part may deform less. For another example, when the user selects a waist area, the waist area may deform more, and an upper torso area and a lower skirt area may deform less.

Euclidean distance refers to a straight-line distance between two points. Euclidean distance may be used to determine the distance between two points on a plane or in three-dimensional (3D) space. When one or more activation areas are determined based on the Euclidean distance from a selected point or area, a pattern or layer that includes the one or more selected points or areas as well as a pattern of another piece of clothing or another layer may be included as the one or more activation areas.

Geodesic distance refers to a distance along a mesh surface of clothing. Geodesic distance may be used to determine a distance on a curved or complex surface of the clothing. When one or more activation areas are determined based on the geodesic distance, activation areas may be determined within a pattern or a layer including the one or more selected points or areas. Alternatively, the one or more activation areas may be determined by extending to adjacent patterns or layers. As described below, when the user selects a waist part of the clothing, the electronic device 1300 may use a geodesic distance to set an activation area along a mesh surface displayed on a graphical user interface.

A linear function refers to a function where a weight decreases linearly with an increase in the distance from a selected point. When the linear function is applied to a weight distribution, a weight decreases at a constant rate as it gets farther away from the selected point so that the weight may be distributed to decrease evenly.

A hat function is a conical function where a weight decreases linearly as the distance increases from a center. When the weight is calculated using the hat function for a sleeve end, the weight distribution decreases linearly from the sleeve end to the shoulder.

The bump function is a Gaussian-shaped function where the weight decreases exponentially as the distance increases from the center. When the weight is calculated using the bump function for a waist part, the weight distribution decreases exponentially as it gets farther away from the waist part.

The sinusoidal function is a function where the weight fluctuates in a periodic pattern. A natural-looking wrinkle may be generated using the sinusoidal function as a periodic weight fluctuation.

According to an embodiment, the electronic device 1300, when determining one or more activation areas, may perform weight painting using smoothing or a bitmap-based brush. Smoothing refers to a process of reducing abrupt changes in weight values or a mesh geometry so that a smooth surface is generated after clothing is deformed. For example, the electronic device 1300 performs smoothing after deforming a sleeve end so that a natural wrinkle is generated. The electronic device 1300 may smoothly change the weight values by averaging adjacent weight values when smoothing. When the user selects a sleeve of the clothing, deforms an activation area, and applies the smoothing, a sleeve part may deform smoothly and naturally.

A bitmap-based brush or a bitmap-based stamp is a tool derived from a bitmap image and may be used for weight painting. The user may employ the brush or the stamp to apply a preset weight, either by increasing or decreasing the weight values. In an activation area, the user may use the brush to paint a weight to emphasize the deformation of a particular part of a specific clothing pattern. For example, when the user selects a sleeve pattern of the clothing and performs deformations on it followed by enhancing the weight values and applying the enhanced weight values to a folded sleeve part by using the brush, a wrinkled part of the sleeve pattern to be deformed is emphasized and thereby more clearly deforms the folded part of the sleeve pattern.

According to an embodiment, the electronic device 1300 may post-process weight values based on at least one of normalization, smoothing, and limiting operations on a specific part of clothing, a mesh, or a pattern.

Normalization refers to a process of adjusting weight values to fall within a certain range. Normalization may be used to prevent the weight values from becoming excessively large or small. For example, the electronic device 1300 normalizes all weight values to values between 0 and 1 after applying the weight values to one or more activation areas.

Smoothing refers to a process of reducing abrupt deformation of a mesh or reducing abrupt changes in weight values. For example, the electronic device 1300 smooths the weight values so that unnatural wrinkles are not formed after deforming a sleeve end.

A limiting operation for a specific part of clothing, a mesh, or a pattern refers to a process of limiting the application of weights to the specific part. The limiting operation may be used to prevent or limit the deformation of the specific part of clothing. For example, the weights are limited for a specific pattern part of the clothing to prevent that part from becoming deformed. When the electronic device 1300 limits the application of the weights to a waist strap pattern part of the clothing, the waist strap pattern part may remain unmodified without being deformed even if a torso pattern is deformed.

In operation 130, the electronic device 1300 may receive motion or displacement for the one or more selected points or areas.

In operation 140, the electronic device 1300 may simulate the one or more activation areas in a deformed state corresponding to the received motion or displacement. The deformation primarily refers to a process where a specific part of clothing changes in response to user input. For example, when the user selects and drags a specific point of the clothing, one or more activation areas make translative movements or change their shapes as a result of the deformation.

According to an embodiment, the electronic device 1300 may sense user input received using a pinching interface applied to a weight-applied area. The pinching interface supports the user in performing operations, such as picking up, dragging, or pulling a specific point.

The electronic device 1300 may run a simulation of picking up a specific point with a finger by moving a specific vertex of clothing or vertices within a certain area based on the user's pinching input. For example, when the user performs the action of picking up a specific point of a sleeve end by using the pinching interface, the electronic device 1300 may detect this input and perform the deformation where the sleeve end rises upward. Detecting such user input and simulation based on such user input may be performed in real time so that the user can better perceive the reaction of the clothing.

According to an embodiment, the electronic device 1300 may detect the user's gizmo input by using a gizmo interface placed on one or more activation areas. The gizmo interface assists the user in performing deformations, such as rotating, making translatory movements, and scaling an object in 3D space. For example, when the user performs a rotation operation using the gizmo interface on a waist part of the clothing, the electronic device 1300 may detect this input and perform a deformation that rotates the waist part.

When the user performs a deformation using the pinching interface or the gizmo interface on a specific part of clothing, the electronic device 1300 may sense this in real time and apply the deformation to the simulation. For example, when the user performs the action of picking up a wrinkled part of clothing with the pinching interface or twisting it with the gizmo interface, the electronic device 1300 may detect this input and deform the wrinkled part naturally in real time.

In the above-described simulation process, a deformation corresponding to the motion or displacement in an intermediate area within the one or more activation areas may be interpolated based on a weight depending on a distance from the selected one or more points or areas. The intermediate area refers to an area within the one or more activation areas between the selected point or selected area and surrounding areas outside the activation areas.

According to an embodiment, the electronic device 1300 may determine the degree of deformation of an intermediate area based on the deformation of one or more selected points or areas. Weights in the intermediate area may be adjusted to values between 0 and 1 based on a user-selected weighting function. A weighted average may be expressed by Equation 1 below. The electronic device 1300 may perform weighted blending as shown in Equation 1 below to display a simulation result corresponding to a deformation in an activation area by the user.

Any vertices with a maximum weight (e.g., w=1) act as kinematic constraints or hard constraints within the physics simulation. These constraints force the physics solver to compute physical updates for the mesh by treating the w=1 vertices as already located at the user-intended position. This process ‘warm-starts’ the solver, allowing forces to propagate naturally to nearby vertices in both the intermediate blending regions and the external simulation areas. Within the solver's integration loop, the blending is performed on displacement vectors (ΔX) to filter the physics step. The logic is expressed by Equation 1:

$$Δ {X}_{final} = ( 1 - w ) \cdot Δ {X}_{solver} + w \cdot Δ {X}_{target} \qquad Equation 1$$

where ΔXₛₒₗᵥₑᵣ denotes a displacement vector that the physics solver applies after applying the hard constraints (w=1), and ΔX_{target} denotes a target displacement vector intended by the user's manipulation. The resulting ΔX_{final} is applied to update vertex positions of the current integration step. Because kinematic constraints are enforced prior to each physics integration step, deformation applied to a selected region may propagate beyond the activation area both within a single simulation step and cumulatively across multiple simulation steps. Accordingly, portions of the clothing mesh that are not directly blended may nevertheless react naturally over time to sustained user manipulation.

According to an embodiment, the electronic device 1300 may perform an interpolation to provide a natural transition between a selected point (or area) and an external simulation area. The external simulation area refers to an area including vertices that are not directly applied with blending weights derived from the user input. Although such vertices are not directly interpolated toward target displacements or motions received from the user, these vertices may nevertheless be affected by the user input through constraint propagation during simulation over time. That is, these vertices may undergo deformation in subsequent physics simulation steps after one or more simulation steps in which constraints of the motion or displacements received from the user were initially applied. Any vertices with a maximum weight (e.g., w=1) act as kinematic constraints or hard constraints within the physics simulation. These constraints force the physics solver to compute physical updates for the mesh, and the physics solver propagates forces from the constrained vertices to nearby vertices, including those in both the intermediate blending regions and the external simulation areas.

For example, when the user deforms a sleeve end, an interpolation may be performed on the deformation in an intermediate area within an activation area so that the sleeve end, which is the selected point, is connected to a shoulder part, which is the external simulation area, in a natural manner.

According to embodiments, the electronic device 1300 may identify an intermediate area where an interpolation is performed for a natural transition between a selected point (or area) and an external simulation area. As used herein, an intermediate area refers to a subset of an activation area that is positioned between one or more user-selected points or areas and portions of the clothing mesh that are not directly constrained by user input. Vertices in the intermediate area are assigned weight values less than a maximum value and greater than zero and are deformed by weighted blending of vertex displacement during the physics simulation to provide a gradual transition between constrained regions and unconstrained regions. The intermediate area may be included in a corresponding activation and is within a predetermined distance from the selected point. In this case, the electronic device 1300 may identify a clearer intermediate area based on a simulation result regarding the activation area and the external simulation area. Accordingly, the electronic device 1300 may adaptively check the predetermined distance from the selected point corresponding to the boundary of the activation area and perform an interpolation of weights for blending the vertex displacements of the intermediate area in physics simulation steps. During the execution of the integration loop of the physics simulation, the blending may be performed on vertex displacement vectors to perform filtering during the physics simulation step rather than performing the filtering on the final mesh positions. Each point in the intermediate area may be blended using weights so that the deformation of the selected point is blended with the motion of the external simulation area in a natural manner.

In an interpolation operation, the electronic device 1300 may determine the motion of the intermediate area within the activation area by using the degree of deformation in the selected point and the motion of the external simulation area. For example, when the user pulls a sleeve end hard and deforms it abruptly, simulations in the intermediate area may form a slightly steep but smooth curve. The external simulation area reacts to the pull through the physics engine even if it is not directly subject to the user's target displacement blending.

According to an embodiment, the electronic device 1300 may adjust the motion of an intermediate area by using weight values during an interpolation. For example, a point with a high weight value may be affected significantly by the deformation of a selected point and thus may deform significantly, while a point with a low weight value may be affected minimally by the deformation of the selected point and result in less deformation.

During an interpolation process, the electronic device 1300 may perform simulations by also using the physical properties of an intermediate area. For example, an interpolation method in the intermediate area may vary depending on the materials or patterns of clothing. For soft-material clothing, a natural simulation may be implemented by using a curved interpolation, while for hard-material clothing, a realistic simulation may be implemented through a linear interpolation.

Accordingly, the electronic device 1300 may interpolate the intermediate area between the selected point and the external simulation area so that the deformation of the whole clothing may be simulated naturally. For example, even when the user deforms a sleeve end significantly, a shoulder part distant from the selected point may be simulated naturally to provide simulations as if the clothing is worn by a person.

Further, as a result of the above-described simulation, the electronic device 1300 may display the intermediate area in an interpolated state, while one or more selected points or areas are displayed in a deformed state, and an external simulation area is displayed in a simulated state.

According to an embodiment, the electronic device 1300 may display one or more selected points or areas, an external simulation area, and an intermediate area in their respective states on a display device.

According to an embodiment, the electronic device 1300 may process a deformation operation input provided by the user, and display one or more activation areas in a deformed and interpolated state according to the input. For example, when the user pulls up a sleeve end, the sleeve end may be displayed on the screen as raised by the user in real time. The deformed state of the sleeve may reflect the form as desired by the user.

According to an embodiment, the electronic device 1300 may interpolate motions between one or more selected points or areas and an external simulation area so that the intermediate area is displayed as connected in a natural manner. For example, when a sleeve end is deformed, the intermediate area within the activation area may be displayed as transitioning naturally between a deformed selected point and the external simulation area. Accordingly, the user may view and confirm, in real time, the simulation in which a deformed part of the clothing is connected to another part of the clothing in its original state.

According to an embodiment, the electronic device 1300 may simulate the state of each of these areas in real time so that the user may view and confirm simulation results of clothing.

In the examples of the embodiments herein, for ease of description, a user-selected point is used as an example, but the user may select an area. For example, when selecting a sleeve end, a part of the sleeve end may be set as an area, and accordingly, the electronic device 1300 may perform the interpolation of an intermediate area and the simulation of an external simulation area according to the deformation of the selected area. In this case, an area (e.g., a circular area) at a certain distance from a user-selected point or an area (e.g., an elliptical area) defined by a certain shape irrespective of the distance may be a user-selected area. A constant distance or a constant shape may be preset by the electronic device 1300 or may be configurable by the user.

In the embodiments described, simulation encompasses the entire clothing simulation process. The simulation may include a representation of how a specific part of the clothing is deformed in response to user input, and how such deformation influences the overall behavior of the clothing. The simulation may be performed to generate the overall motion of the clothing, including the deformation of one or more activation areas and areas outside the one or more activation areas. The electronic device 1300 may simulate how the clothing reacts and deforms based on the user's manipulation by using the physical properties of the clothing through physics simulation. A physics simulation may provide a realistic representation of the behavior of clothing based on its materials or properties and external forces resulting from user input and/or environmental conditions.

According to an embodiment, the electronic device 1300 may simulate deformation of one or more activation areas depending on weights and an external simulation area, based on the physical properties of fabric applied to clothing. For example, depending on the physical properties, such as material properties, thickness, or length, of the fabric applied to the clothing, interpolations and deformations may vary in one or more activation areas, and simulation in the external simulation areas may also vary. The electronic device 1300 may simulate the appearance of deformed clothing when the clothing is actually worn. Consequently, the electronic device 1300 may simulate interpolations and deformations in one or more activation areas based on user input of motion or displacement and perform simulations in external simulation areas to reflect various styles and shapes of clothing according to the user's manipulation.

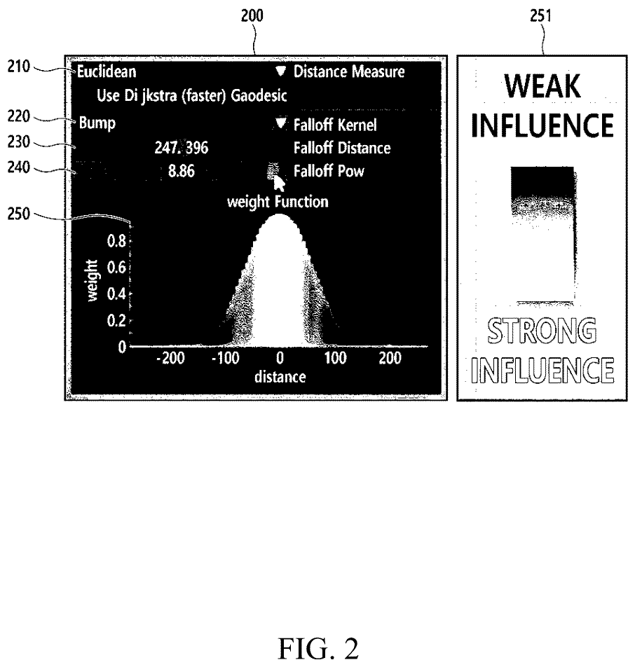

FIG. 2 is a graphical user interface diagram illustrating an area adjustment interface, according to an embodiment. According to an embodiment, the electronic device 1300 may provide an area adjustment interface as a user interface for receiving one or more points or areas. The area adjustment interface 200 may include a Distance measure menu 210, a Falloff kernel menu 220, a Falloff distance menu 230, a Falloff Power menu 240, and a weight distribution 250. An influence 251 based on a weight distribution may be represented as a spectrum to visually illustrate the weight distribution 250.

The area adjustment interface 200 may provide a user with various options for adjusting weight for a specific part of clothing. The user may precisely set the weight calculation method and distribution through the area adjustment interface 200.

The Distance measure menu 210 is a menu for selecting a distance measurement method to be used when calculating a weight. For example, the user may select Euclidean distance (or straight) or geodesic distance (or intrinsic, geodetic, surface, etc.).

The Falloff kernel (or Falloff shape) menu 220 is for selecting a function that determines the shape of the weight distribution. The user may select from available functions, such as a linear function, a hat function, a bump function, or a sinusoidal function. The hat function may provide a conical weight distribution, and the bump function may provide a Gaussian weight distribution. The sinusoidal function may provide a weight distribution having a periodic pattern.

The Falloff distance menu 230 is a menu for setting the range of a weight distribution. The user may set a maximum distance from one or more selected points (or areas) to be applied with weights. For example, the weight may be applied within a specific area, such as a distance from a sleeve end to a shoulder.

The Falloff Power menu 240 is a menu for adjusting the strength of a weight distribution. The user may set a rate of decrease of the weight distribution. A weight distribution with a high value may decrease rapidly, while a weight distribution with a low value may decrease gradually.

The weight distribution 250 may visually display the distribution of weights calculated with selected Falloff kernel, Falloff distance, or Falloff power settings. The user may view in real time how set values influence the weight distribution.

The influence 251 may explain what is shown in the weight distribution 250. Specifically, influence 251 visually shows how the degree of influence from low to high weight is shown by different colors in the weight distribution 250.

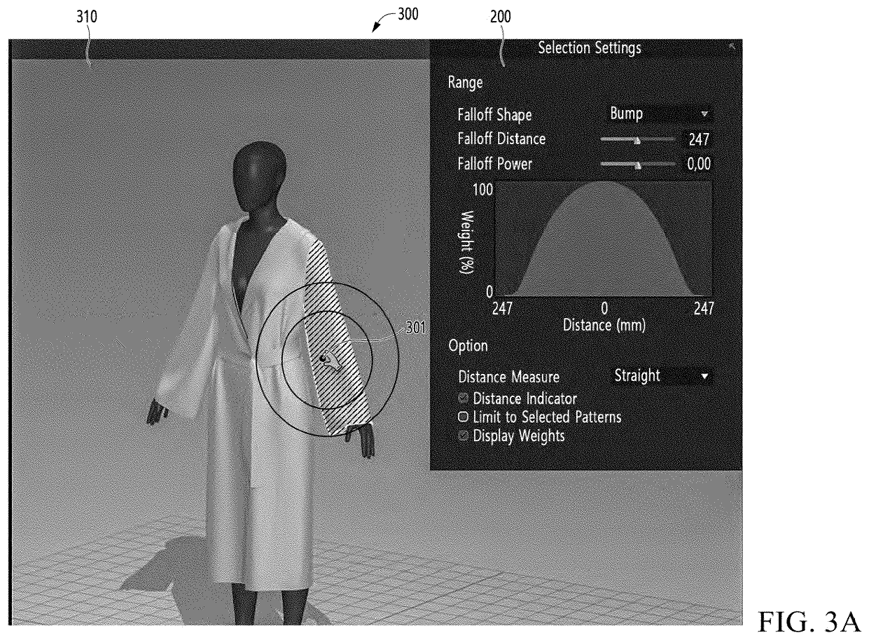

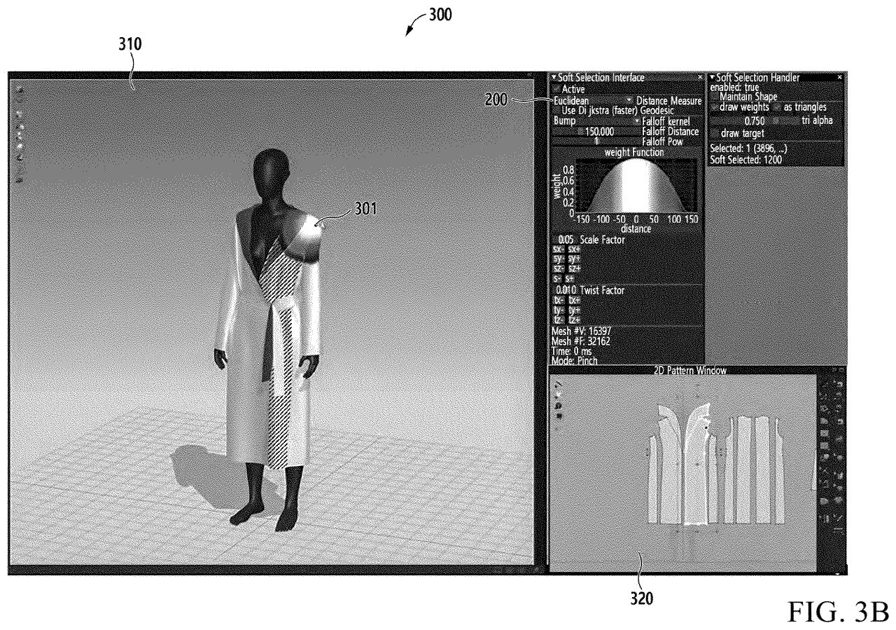

FIGS. 3A and 3B are graphical user interface diagrams illustrating an activated state of soft selection, according to an embodiment. A user interface 300 may be an interface that provides various tools and settings that allow a user to select and modify a specific part of clothing. The user interface 300 may include a 3D modeling area 310, a 2D pattern area 320, and an area adjustment interface 200.

A soft selection activation area 301 may be one or more activation areas within a preset distance from one or more selected points or areas. The soft selection activation area 301 may visually display weights of the one or more activation areas and allow the user to clearly recognize an area to be modified. The soft selection activation area 301 may visually indicate on a specific part of clothing using a color or gradient, with the degree of influence represented by the intensity or variation of the color or gradient. For example, when the soft selection activation area 301 from a shoulder area to a chest area is selected, the soft selection activation area 301 may be naturally deformed based on the user's deformation and weight.

Depending on the settings of the user interface 300, the user may visually check the weight in the soft selection activation area 301 by clicking. Initially, weight painting is not performed on the soft selection activation area 301, as shown in FIG. 3A. Once the user clicks, the weight painting is performed and displayed, as shown in FIG. 3B. On the other hand, when the weight painting is set to be displayed continuously, the weight painting of the soft selection activation area 301 may be displayed continuously while the user's cursor is hovering over the clothing.

The 3D modeling area 310 may be an area where clothing and a user-selected avatar are displayed in 3D. The user may select a specific part of the clothing in the 3D modeling area 310 and deform it in real time. As described above, the area adjustment interface 200 may provide various menus for adjusting the weight of the soft selection activation area 301. The soft selection activation area 301 may be a part of clothing where the weights of the one or more activation areas are displayed in a 3D model window.

The 2D pattern area 320 may be an area that displays a pattern of clothing displayed in the 3D modeling area 310 in 2D so that the user may edit or adjust the pattern. The user may check the soft selection activation area 301 in the 2D pattern area 320 and check a pattern that is being currently edited.

The 2D pattern area 320 may display the user's soft selection activation area 301 in the 3D modeling area 310 corresponding to a soft selection activation function. In addition, even when at least a part of the clothing displayed in the 3D modeling area 310 is layered, the electronic device 1300 may show the soft selection activation area 301 on individual patterns in the 2D pattern area 320 by using weights applied to layered patterns in the 3D modeling area 310 based on a matrix that maps the coordinates of the individual patterns in the 2D pattern area 320 to the coordinates of individual patterns in the 3D modeling area 310.

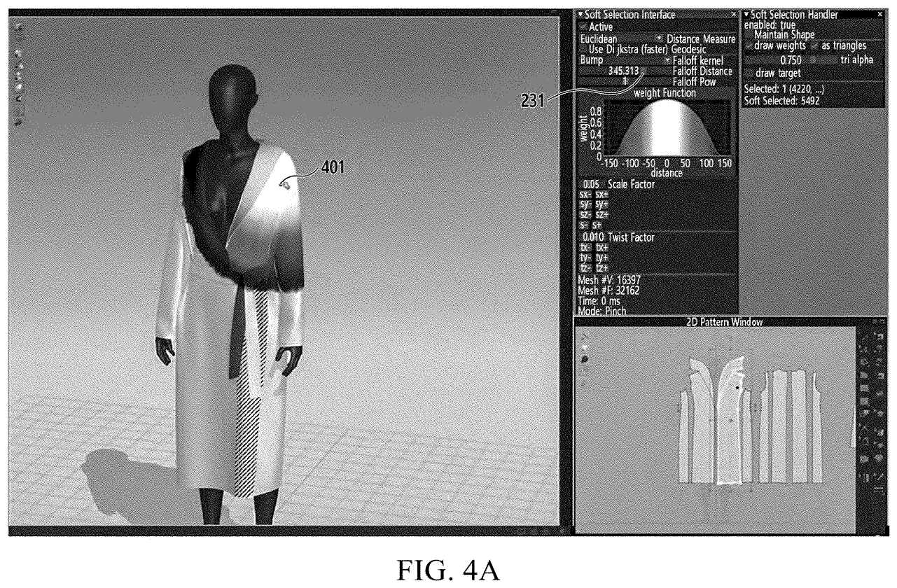

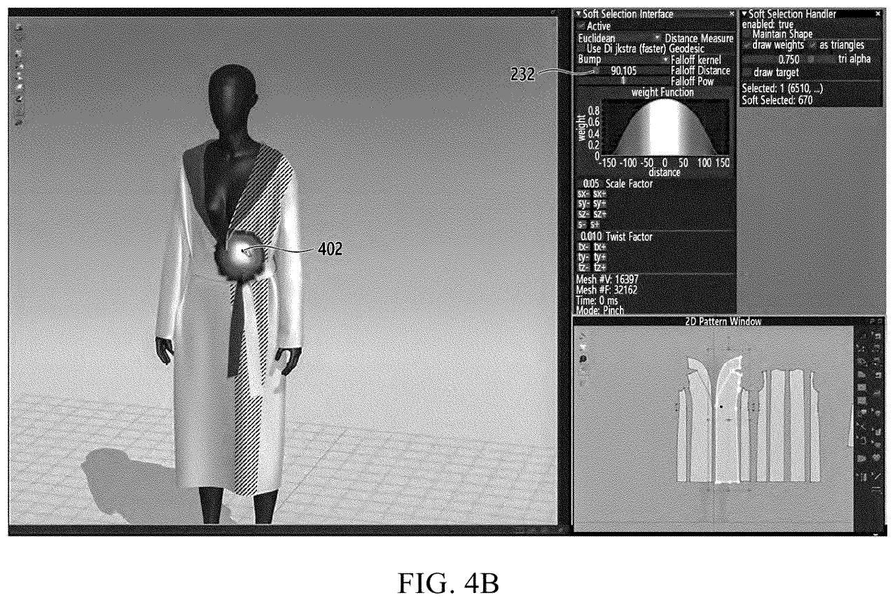

FIGS. 4A and 4B are graphical user interface diagrams illustrating deformations in a soft selection activation area according to falloff distance adjustment, according to an embodiment. Referring to FIG. 4A, a soft selection activation area 301 may be modified to increase its size so that an area to be applied with weights according to the adjustment of a Falloff Distance in a Falloff Distance menu 230 is increased.

For example, when the user moves an adjustment bar of the Falloff Distance menu 230 to the right to significantly increase the Falloff Distance of the Falloff Distance menu 230 and adjusts it to a first Falloff Distance 231, the soft selection activation area 301 may be changed to a first Falloff Distance activation area 401.

Referring to FIG. 4B, the soft selection activation area 301 may be modified to decrease its size so that the area to be applied with weights according to the adjustment of the Falloff Distance in the Falloff Distance menu 230 is decreased. When the user moves the adjustment bar of the Falloff Distance menu 230 to the left to significantly change the Falloff Distance of the Falloff Distance menu 230 and adjusts it to a second Falloff Distance 232, the soft selection activation area 301 may be changed to a second Falloff Distance activation area 402.

The Falloff Distance may determine a range over which weights in one or more activation areas decrease and influence the size and shape of the soft selection activation area 301. When the Falloff Distance is set to have a great value, like the first Falloff Distance 231, a weight may decrease over a wider range, and the soft selection activation area 301 may be modified into a wider shape. Conversely, when the Falloff Distance is set to have a low value, like the second Falloff Distance 232, a weight is applied to a narrower range, and the soft selection activation area 301 may deform into a smaller shape.

The user may adjust the size and shape of the soft selection activation area 301 through the Falloff Distance menu 230 to apply a weight to a desired part with desired intensity.

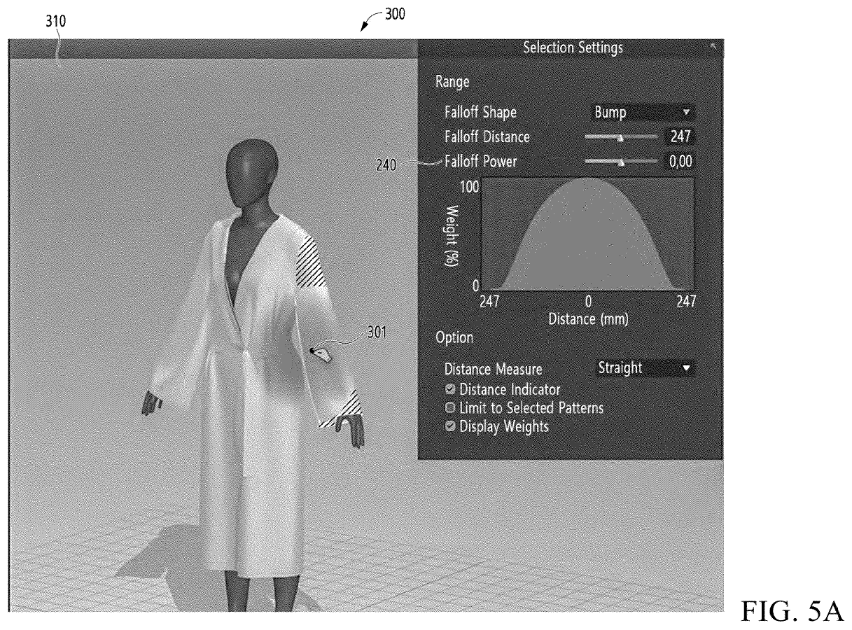

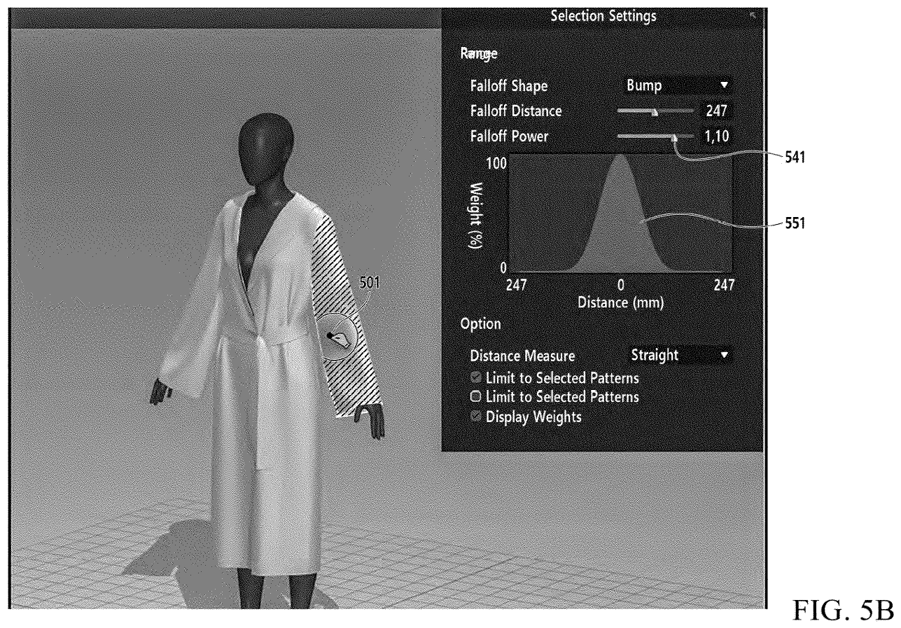

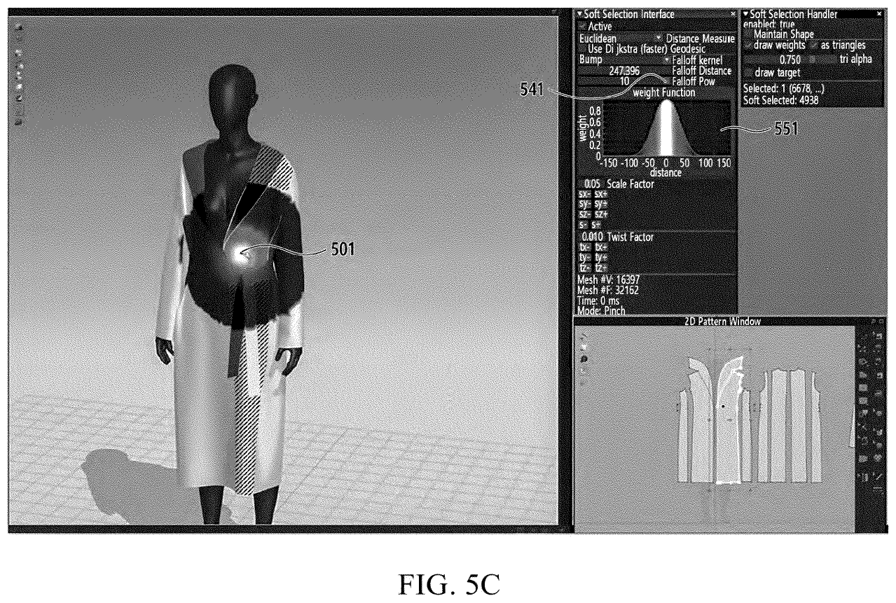

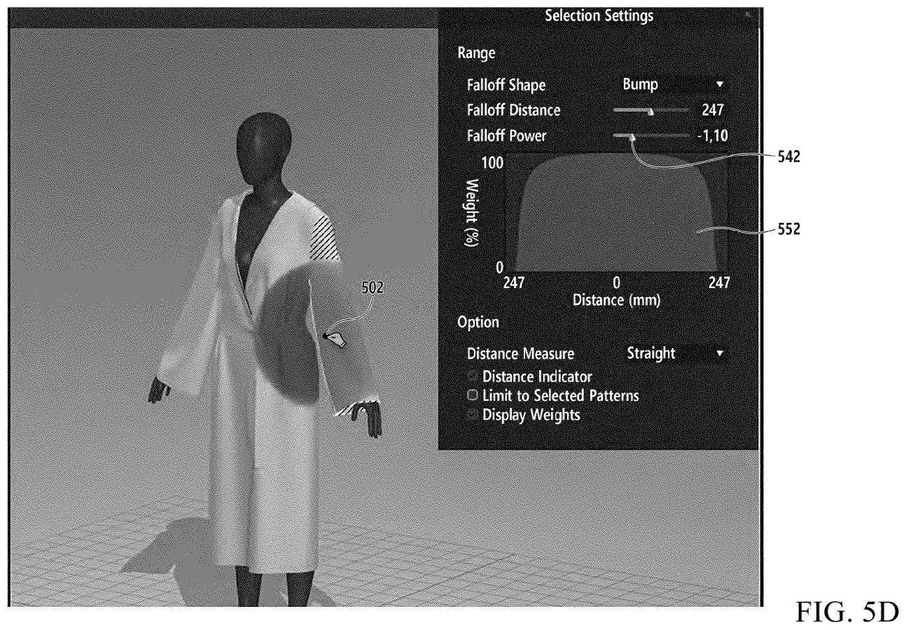

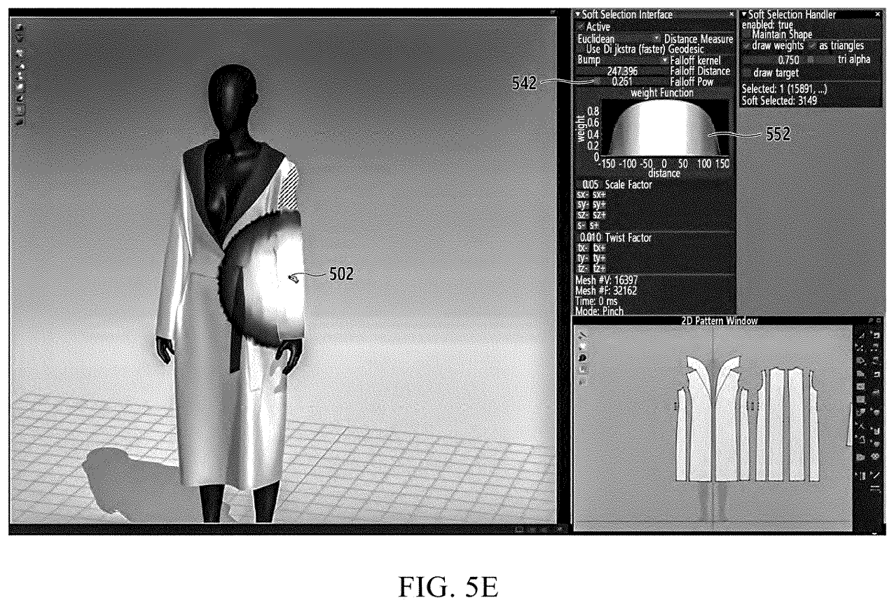

FIGS. 5A through 5E are graphical user interface diagrams illustrating transformation of soft selection activation area, according to falloff power adjustment, according to an embodiment. A method for applying a weight to a soft selection activation area 301 may vary depending on the adjustment of Falloff Power in a Falloff Power menu 240. For example, when the user moves an adjustment bar to the right and sets the Falloff Power high in the Falloff Power menu 240, adjusting to a first Falloff Power 541, the soft selection activation area 301 may be modified like a first Falloff Power activation area 501. A first Falloff Power weight distribution 551 may visually show how weights are distributed according to this setting.

Referring to FIGS. 5A, 5D, and 5E, how weights are applied to the soft selection activation area 301 may vary depending on the adjustment in Falloff Power in a Falloff Power menu 240. For example, when the user moves an adjustment bar to the left and sets the Falloff Power low in the Falloff Power menu 240, adjusting to a second Falloff Power 542, the soft selection activation area 301 may be modified like a second Falloff Power activation area 502. A second Falloff Power weight distribution 552 may visually show how weights are distributed according to this setting.

The Falloff Power determines the strength of a weight reduction in one or more activation areas, which may influence the weight distribution of soft selection activation areas. Setting Falloff Power to the first Falloff Power 541 may cause the weights to be modified to influence a narrower range within the same area. Setting Falloff Power to the second Falloff Power 542 may cause the weights to be modified to influence a wider range within the same area.

The user may adjust the weight distribution of the soft selection activation area 301 through the Falloff Power menu 240 to apply a weight to a desired part with a desired intensity.

In the embodiments described with reference to FIGS. 4A through 5E, the Falloff Distance menu 230 and the Falloff Power menu 240 are shown in the form of adjustment bars for adjusting numerical values. In other embodiments, other user interface elements such as entry fields for receiving a direct input of a desired value from the user may be used instead.

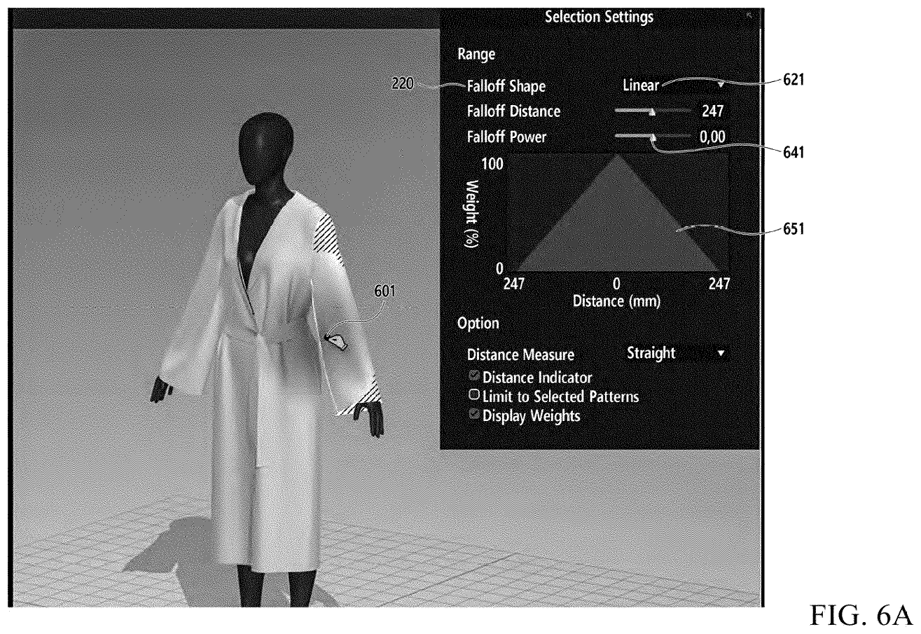

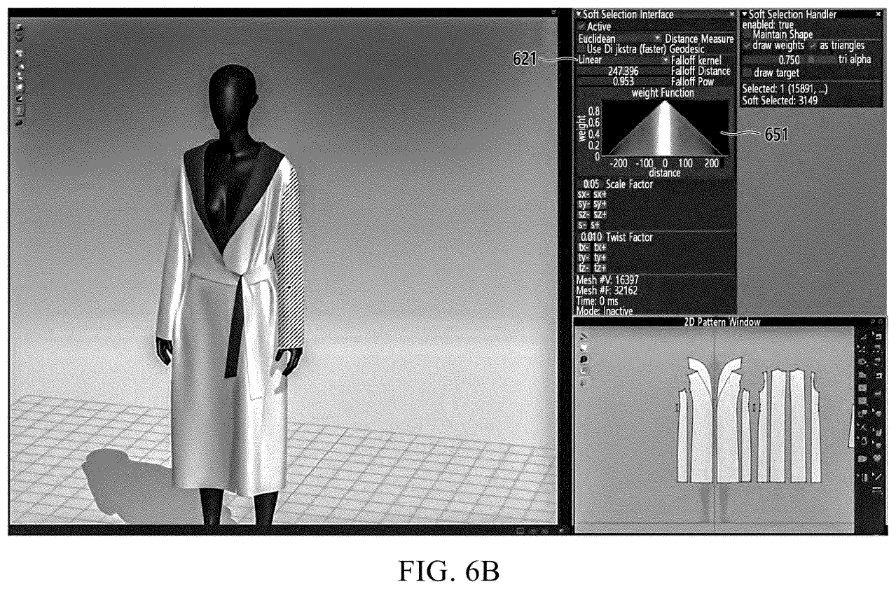

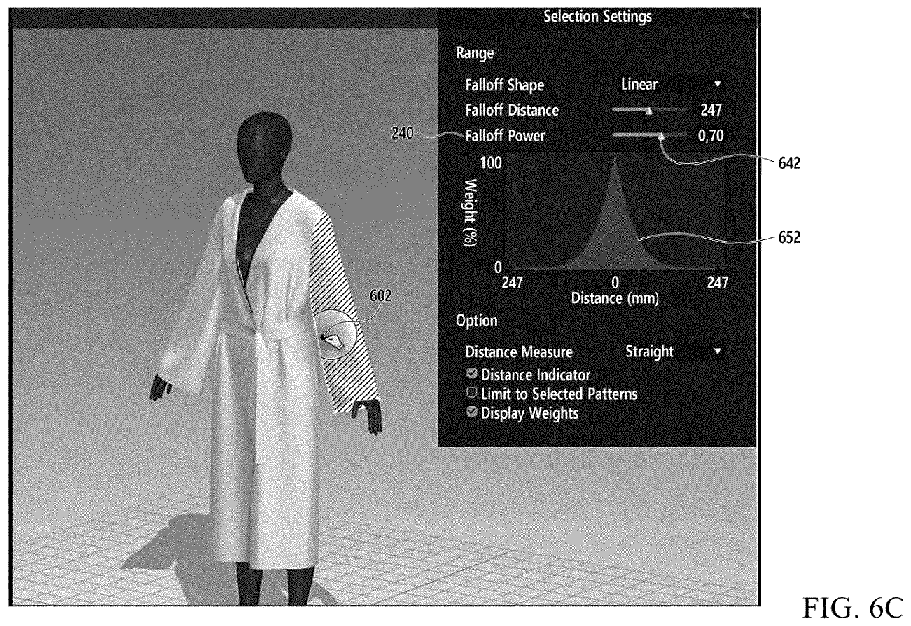

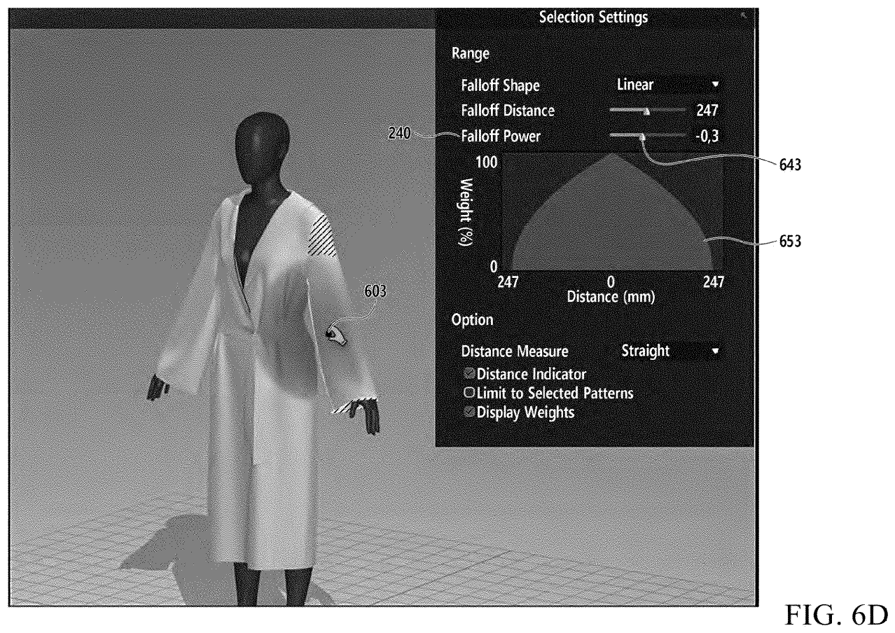

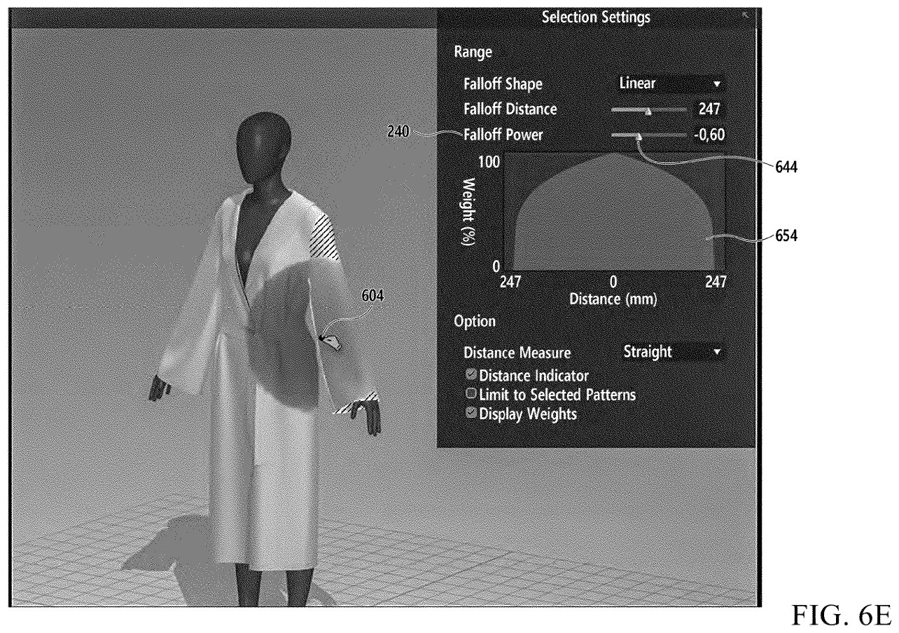

FIGS. 6A through 6E are graphical user interface diagrams illustrating changes in a weight distribution by adjusting a falloff kernel, according to an embodiment. Referring to FIGS. 6A and 6B, when the user selects a linear function 621 from a Falloff Kernel (or Falloff Shape) menu 220, the weight distribution of a soft selection activation region 301 may change into a first linear weight distribution 651. In this case, weights may have a distribution that linearly decreases with the distance from a selected point in a first linear Falloff Power 641. That is, the soft selection activation region 301 may be set to a first linear activation area 601.

The area adjustment interface 200 may provide the user with various options for adjusting the weight distribution through the Falloff Kernel menu 220. The available functions are not limited to the embodiments described.

Referring to FIG. 6C, when the user changes a Falloff Power menu 240 to a second linear Falloff Power 642, the weight distribution of the first linear activation area 601 may be changed into a second linear weight distribution 652. In this case, the weights vary depending on the value of the second linear Falloff Power 642 according to the distance from the selected point, and the first linear activation area 601 may be changed into the second linear activation area 602.

Referring to FIG. 6D, when the user changes the Falloff Power menu 240 to a third linear Falloff Power 643, the weight distribution of the second linear activation area 602 (or the first linear activation area 601) may be changed into a third linear weight distribution 653. In this case, the weights vary depending on the value of the third linear Falloff Power 643 based on the distance from the selected point, and the second linear activation area 602 (or the first linear activation area 601) may be changed into the third linear activation area 603.

Referring to FIG. 6E, when the user changes the Falloff Power menu 240 to a fourth linear Falloff Power 644, the weight distribution of the third linear activation area 603 (or the first linear activation area 601 or the second linear activation area 602) may be changed into a fourth linear weight distribution 654. In this case, the weights vary depending on the value of the fourth linear Falloff Power 644 based on the distance from the selected point, and the third linear activation area 603 (or the first linear activation area 601 or the second linear activation area 602) may be changed into a fourth linear activation area 604.

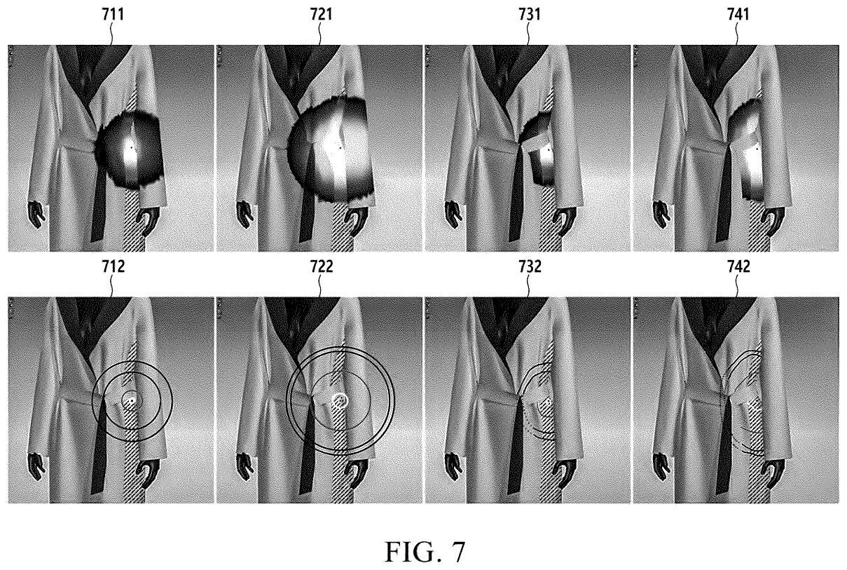

FIG. 7 is a diagram schematically illustrating Euclidean distance and geodesic distance, according to an embodiment. An example of a soft selection activation area 301 based on Euclidean distance and geodesic distance is illustrated. A Euclidean gradient brush initial state 711 represents the soft selection activation area 301 based on Euclidean distance in the form of a gradient brush. The weights may decrease with the distance from a user-selected point or area and are displayed as a gradient.

A Euclidean circle brush initial state 712 represents the Euclidean gradient brush initial state 711 in the form of a circle brush in an initial state of the soft selection activation area 301 based on Euclidean distance in the form of a circle brush. An area within a certain radius from the selected point or area may be determined, and as the radius increases, the soft selection activation area 301 may become larger.

A Euclidean gradient brush extended state 721 represents an expanded state of the soft selection activation area 301 based on Euclidean distance. The weights may decrease with the distance from a user-selected point or area and are displayed as a gradient.

A Euclidean circle brush extended state 722 represents the Euclidean gradient brush extended state 721 in the form of a circle brush and represents an extended state of the soft selection activation area 301 based on Euclidean distance in the form of a circle brush. An area within a certain radius from the user-selected point or area may be determined, and as the radius increases, the soft selection activation area 301 may become larger.

A geodesic gradient brush initial state 731 represents an initial state of the soft selection activation area 301 based on geodesic distance in the form of a gradient brush. The electronic device 1300 may calculate a distance along a mesh surface of clothing on the user interface 300, display a soft selection activation area 301 corresponding to a user-selected point or area, and indicate changes in weights using a gradient.

A geodesic circle brush initial state 732 represents the geodesic gradient brush initial state 731 in the form of a circle brush and represents an initial state of the soft selection activation area 301 based on geodesic distance in the form of a circle brush. The electronic device 1300 may calculate a distance along the mesh surface of the clothing on the user interface 300 and represent the soft selection activation area 301 corresponding to a user-selected point or area as a circle brush.

A geodesic gradient brush extended state 741 represents an expanded state of the soft selection activation area 301 based on geodesic distance. The electronic device 1300 may calculate a distance along a mesh surface of clothing on the user interface 300, display a soft selection activation area 301 corresponding to a user-selected point or area, and indicate changes in weights using a gradient.

A geodesic circle brush extended state 742 represents the geodesic gradient brush extended state 741 in the form of a circle brush and represents an extended state of the soft selection activation area 301 based on geodesic distance in the form of a circle brush. The electronic device 1300 may calculate a distance along the mesh surface of the clothing on the user interface 300 and represent the soft selection activation area 301 corresponding to a user-selected point or area as a circle brush.

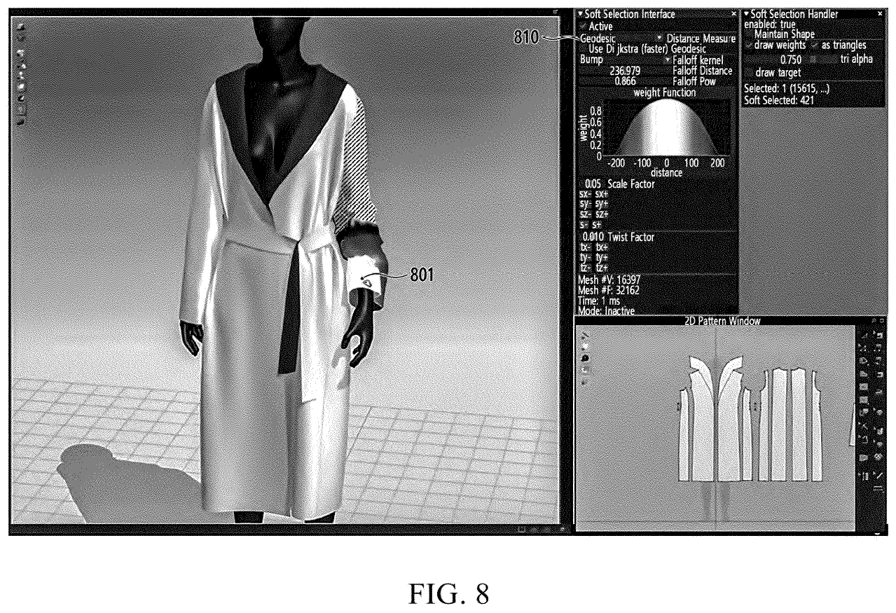

FIG. 8 is a graphical user interface diagram illustrating geodesic distance-based soft selection according to an embodiment. When a user selects geodesic distance 810 from a Distance Measure menu 210 in an area adjustment interface 200 and selects a sleeve of clothing, the electronic device 1300 may recognize the selection and set a soft selection activation area 301 as a geodesic activation area 801. The electronic device 1300 may calculate a distance along a mesh surface of clothing from a selected point and represent an area corresponding to a user-selected point based on geodesic distance 810.

The electronic device 1300 may visually display one or more activation areas on a user interface 300 based on the geodesic distance 810 when the user selects a specific part of clothing. For example, when the user selects a sleeve part, the selected sleeve part may be displayed as the geodesic activation area 801.

The soft selection activation area 801 based on geodesic distance may calculate a distance along a mesh surface of clothing from a selected point and assign weights depending on the distance from the selected point. In this case, the electronic device 1300 may calculate a weight distribution according to a function of a Falloff Kernel menu 220 set by the user and adjust the deformation of one or more activation areas.

When the user selects a distance metric based on the geodesic distance 810, selects a sleeve part, and drags it to deform the sleeve, the deformation of the sleeve part may be performed while the mesh surface outside one or more activation areas is not influenced by the user's drag.

The electronic device 1300 may perform deformations by considering the physical properties of one or more activation areas. For example, a smoothing function may be applied so that the sleeve part deforms smoothly, or a weight in a specific part may be limited to preserve the pattern or design of the clothing.

In addition, the electronic device 1300 may display the deformation results of one or more activation areas on the screen in real time. When the user selects and deforms a sleeve, the selected sleeve part may be displayed as the geodesic distance-based activation area 801, and the deformed state may be reflected in real time. By viewing the deformation in real time, the user may verify the deformation result and readily perform necessary adjustments.

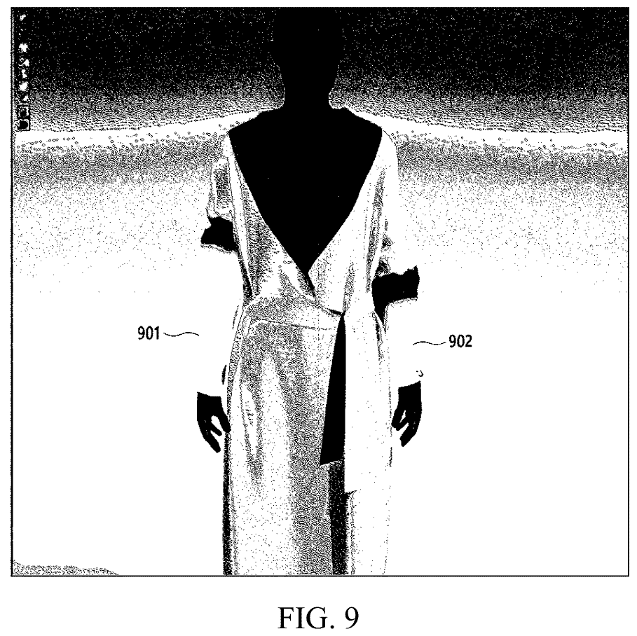

FIG. 9 is a diagram schematically illustrating multi-soft selection, according to an embodiment. Referring to FIG. 9, a user may select multiple areas of clothing at once to perform multi-soft selection. The electronic device 1300 may generate soft selection activation areas 901 and 902 for each selected point or area when the user selects one or more points or areas through a user interface. In this case, each selected point or area may individually calculate a weight and be deformed. For example, when the user selects both sleeve parts simultaneously, soft selection activation areas 901 and 902 may be generated respectively for each sleeve part, thereby allowing the user to deform both sleeves at the same time.

If the multi-soft selection activation areas 901 and 902 are based on geodesic distance, a distance may be calculated along a mesh surface of clothing from one or more selected points or areas, and weights may be assigned depending on the distance from each selected point. In this case, the electronic device 1300 may calculate the weight distribution of each of one or more activation areas and control the deformation of each area.

The user may deform multiple parts of clothing simultaneously through the multi-soft selection function. For example, when the user selects both sleeve parts and drags to deform them, both sleeve parts may be deformed simultaneously.

The embodiments described may apply not only to selections of two parts but also to multiple areas. The user may select and deform multiple points or areas simultaneously, and the electronic device 1300 may individually generate soft selection activation areas for each selected point or area and perform the deformation.

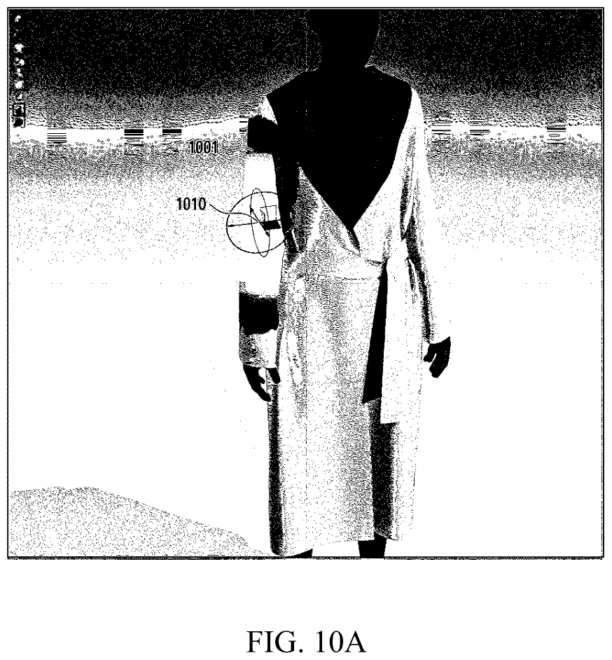

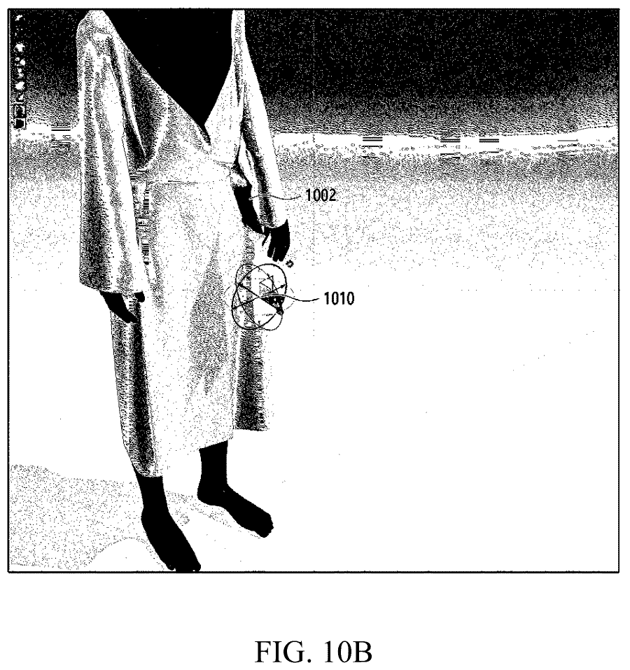

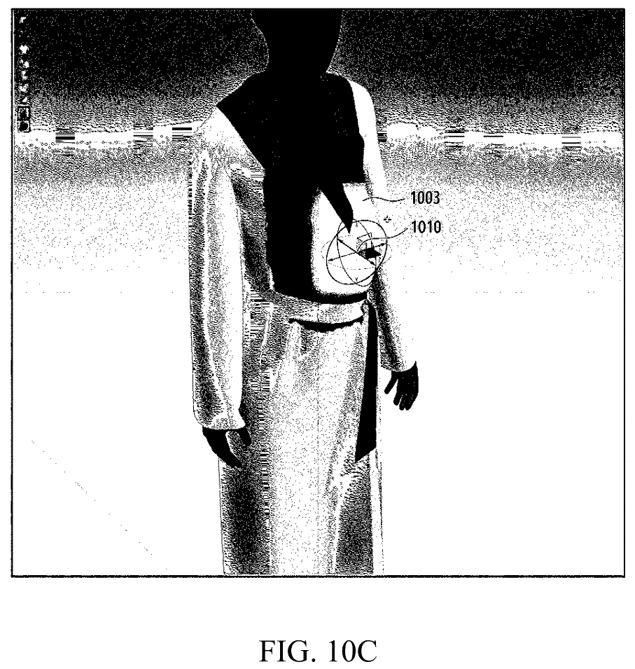

FIGS. 10A to 10C are graphical user interface diagrams illustrating the operation of a gizmo interface, according to an embodiment. FIGS. 10A to 10C each illustrate the operation of a gizmo interface 1010. The electronic device 1300 may receive a user's gizmo input through a gizmo interface and perform simulations on geodesic distance-based arm soft selection activation area 1001, a waist strap soft selection activation area 1002, and a front torso soft selection activation area 1003.

The gizmo interface 1010 is a tool that assists the user in deforming selected areas, and the user may freely manipulate one or more activation areas through the gizmo interface. The electronic device 1300 may receive an input from the user selecting a specific point or area through the user interface 300 and set a soft selection activation area for one or more selected points or areas. The user may use the gizmo interface 1010 to deform one or more selected points or areas, and the deformation may be performed based on geodesic distance.

FIG. 10A illustrates deformations performed by using the gizmo interface 1010 in the arm soft selection activation area 1001. A user may select an arm part and perform deformations, such as rotation, translation, and scaling, using the gizmo interface. For example, when the user inputs a folding-up translative movement of the arm part in the arm soft selection activation area 1001 through the gizmo interface 1010, the electronic device 1300 may receive the translation input and simulate the arm part folding up.

FIG. 10B illustrates deformations performed using the gizmo interface 1010 in the waist strap soft selection activation area 1002. A user may select a waist strap part and perform deformations, such as rotation, translation, and scaling, using the gizmo interface. For example, when the user inputs a rotation input of a waist strap through the gizmo interface 1010 in the waist strap soft selection activation area 1002, the electronic device 1300 may receive the rotation input and simulate a twisted waist strap.

FIG. 10C illustrates deformations performed by using the gizmo interface 1010 in the front torso soft selection activation area 1003. A user may select a front torso part and perform deformations, such as rotation, translation, and scaling, using the gizmo interface. For example, when the user inputs an input for pulling the front of the torso through the gizmo interface 1010 in the front torso soft selection activation area 1003, the electronic device 1300 may receive the input for the translative movement and simulate the front of the torso translating along the gizmo interface 1010.

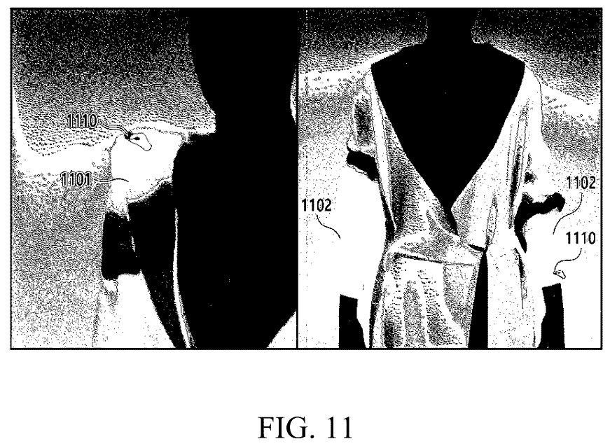

FIG. 11 is a diagram schematically illustrating a pinching interface according to an embodiment. Referring to FIG. 11, a shoulder soft selection activation area 1101 and sleeve soft selection activation areas 1102 may be deformed by a pinching interface 1110. The pinching interface 1110 is an interface that assists the user in deforming a selected area. The user may freely manipulate one or more activation areas through pinching.

The user may select the shoulder soft selection activation area 1101 through the pinching interface 1110 and perform a pulling action. When the user selects a shoulder part and drags it by using the pinching interface 1110, the shoulder soft selection activation area 1101 may deform. The pinching interface 1110 may receive an input that allows the user to perform the action of picking up or pulling a specific point with two fingers, causing the electronic device 1300 to simulate the shoulder soft selection activation area 1101 as intended by the user in real time.

In an embodiment, the pinching interface allows for arbitrary movement of the selected vertices. When a user clicks a point on the screen, a 3D ray is generated via camera information to identify the closest cloth vertex. As the user drags the mouse, the screen-space movement is converted into a 3D displacement vector (Δx) in an arbitrary direction, which is not limited to the mesh normal. This displacement is then used to update target positions for soft-selected vertices, serving as both solver constraints and target displacements for the blending process. For example, the displacement vector may coincide with the normal direction, but is not limited thereto.

A sleeve rolling up may be simulated with the user dragging the sleeve soft selection activation area 1102 by using the pinching interface 1110. When the user selects a sleeve part and drags it by using the pinching interface 1110, the sleeve soft selection activation areas 1102 deform so that the sleeve rolls up in a natural fashion.

The electronic device 1300 may reflect the deformation of one or more activation areas received through the pinching interface 1110 in real time to the 3D modeling area 310. When the user selects a shoulder or sleeve part and deforms it using the pinching interface, the selected shoulder soft selection activation area 1101 and sleeve soft selection activation areas 1102 may be displayed on the screen in real time in a deformed state.

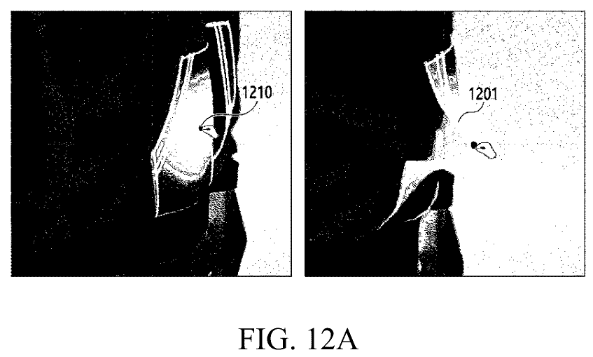

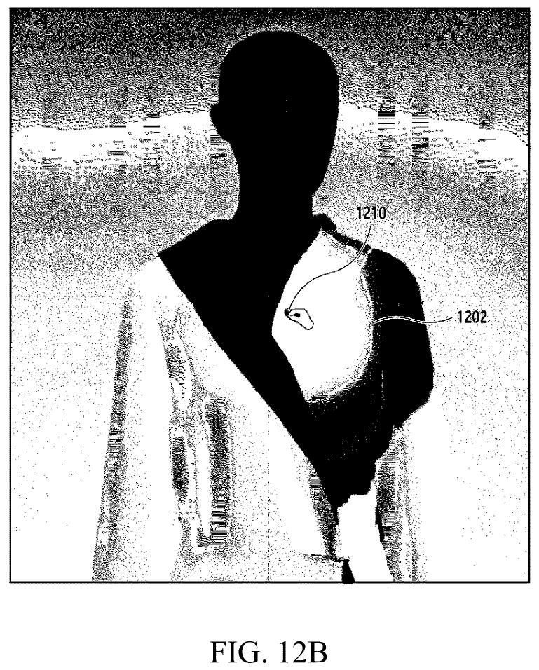

FIGS. 12A and 12B are diagrams, each schematically illustrating a pinching interface according to an embodiment. Referring to FIGS. 12A and 12B, a user may use a pinching interface 1210 to deform and simulate a specific part of clothing. The electronic device 1300 may receive the user's pinching input and deform a pocket soft selection activation area 1201 and a collar soft selection activation area 1202. In this case, the electronic device 1300 may perform deformations and simulations by selecting a specific layer (or pattern) from the clothing in response to the user's pinching input.

Referring to FIG. 12A, the electronic device 1300 may perform simulations based on the user's pinching input received from a pinching interface 1210 in a pocket soft selection activation area 1201. When the user selects the front part of a pocket, which is one of the layers of a pocket part, and pulls it using the pinching interface 1210, the pocket soft selection activation area 1201 may be assigned to the front part of the pocket and be deformed based on the user's pinching input. The pinching interface 1210 may receive an input regarding the user's action of pulling or picking up the selected layer, which is the front of the pocket, with two fingers.

Referring to FIG. 12B, the electronic device 1300 may receive a pinching input through a pinching interface 1210 to specify a collar soft selection activation area 1202 and perform simulations. When the user selects a right collar, which is one of the layers of a collar part, and drags it using the pinching interface 1210, a collar soft selection activation area 1202 may deform and be simulated.

The electronic device 1300 may simulate the deformation of the selected layer in real time through the pinching interface 1210. When the user selects a specific layer of a pocket or collar part and deforms it using a pinching interface, the selected pocket soft selection activation area 1201 and collar soft selection activation area 1202 may be displayed in real time on the user interface 300 in a deformed state.

FIG. 13 is a block diagram illustrating an electronic device according to an embodiment. Referring to FIG. 13, the electronic device 1300 may include a processor 1330, memory 1350, and an output device 1370 (e.g., a display). The processor 1330, the memory 1350, and the output device 1370 may be connected to one another via a communication bus 1305.

The output device 1370 may display clothing simulations provided by the processor 1330 together with a user interface.

The memory 1350 may store simulation results related to soft selection performed by the processor 1330. In addition, the memory 1350 may store various pieces of information generated in the process of the processor 1330 described above. In addition, the memory 1350 may store various pieces of data, programs, or the like. The memory 1350 may include a volatile memory or a non-volatile memory. The memory 1350 may include a massive storage medium, such as a hard disk, and store the various pieces of data.

In addition, the processor 1330 may perform at least one method described with reference to FIGS. 1 to 9 or an algorithm corresponding to the at least one method. The processor 1330 may be a data processing device implemented by hardware including a circuit having a physical structure to perform desired operations. For example, the desired operations may include code or instructions in a program. The processor 1330 may be implemented as, for example, a central processing unit (CPU), a graphics processing unit (GPU), or a neural network processing unit (NPU). The hardware-implemented electronic device 1000 may include, for example, a microprocessor, a CPU, a processor core, a multi-core processor, a multiprocessor, an application-specific integrated circuit (ASIC), and a field-programmable gate array (FPGA).

The processor 1330 may execute a program and control the electronic device 1000. The code of the program executed by the processor 1330 may be stored in the memory 1350.

The examples described herein may be implemented by using a hardware component, a software component, and/or a combination thereof. A processing device may be implemented using one or more general-purpose or special-purpose computers, such as, for example, a processor, a controller and an arithmetic logic unit (ALU), a digital signal processor (DSP), a microcomputer, a field-programmable gate array (FPGA), a programmable logic unit (PLU), a microprocessor, or any other device capable of responding to and executing instructions in a defined manner. The processing device may run an operating system (OS) and one or more software applications that run on the OS. The processing unit also may access, store, manipulate, process, and generate data in response to execution of the software. For the purpose of simplicity, the description of a processing unit is used as singular; however, one skilled in the art will appreciate that a processing unit may include multiple processing elements and multiple types of processing elements. For example, the processing unit may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described examples may be recorded in non-transitory computer-readable media including program instructions to implement various operations of the above-described examples. The media may also include, alone or in combination with the program instructions, data files, data structures, and the like. The program instructions recorded on the media may be those specially designed and constructed for the purposes of examples, or they may be of the kind well-known and available to those having skill in the computer software arts. Examples of non-transitory computer-readable media include magnetic media such as hard disks, floppy disks, and magnetic tape; optical media such as CD-ROM discs and/or DVDs; magneto-optical media such as optical discs; and hardware devices that are specially configured to store and perform program instructions, such as read-only memory (ROM), random-access memory (RAM), flash memory, and the like. Examples of program instructions include both machine code, such as produced by a compiler, and files containing higher-level code that may be executed by the computer using an interpreter.

The above-described devices may act as one or more software modules in order to perform the operations of the above-described examples, or vice versa.

As described above, although the examples have been described with reference to the limited drawings, a person skilled in the art may apply various technical modifications and variations based thereon. For example, suitable results may be achieved if the described techniques are performed in a different order and/or if components in a described system, architecture, device, or circuit are combined in a different manner and/or replaced or supplemented by other components or their equivalents.

Therefore, other implementations, other examples, and equivalents to the claims are also within the scope of the following claims.

What is claimed is:

1. A clothing simulation method comprising:
receiving selection of one or more points or areas of clothing;
receiving a motion or a displacement associated with the one or more points or areas;
determining one or more activation areas including the one or more selected points or areas and an intermediate area around the one or more selected points or areas, the one or more selected points or areas constrained by the received motion or the displacement in one or more physics simulation steps, the intermediate area partially constrained by the motion or the displacement in the one or more physics simulation steps;
receiving the motion or the displacement of the one or more selected points or areas; and
simulating the clothing with the one or more selected points or areas constrained according to the received motion or displacement in the physics simulation steps, and the intermediate area partially constrained according to the received motion or displacement in the physics simulation steps.

2. The clothing simulation method of claim 1, further comprising:
displaying deformation of the one or more selected points or areas in real time responsive to receiving the motion or the displacement of the one or more selected points or areas.

3. The clothing simulation method of claim 1, wherein the motion comprises at least one of rotation, translation, scaling, or twisting.

4. The clothing simulation method of claim 1, wherein the one or more activation areas are defined by a distance from the selected points or areas represented in Euclidean distance or geodesic distance.

5. The clothing simulation method of claim 1, further comprising determining the one or more activation areas by performing smoothing or weight painting using a bitmap-based brush or stamp.

6. The clothing simulation method of claim 5, wherein the determining of the one or more activation areas further comprises normalization of weight values for blending or limiting the activation areas to a specific part of the clothing, a mesh of the clothing, or a pattern of the clothing.

7. The clothing simulation method of claim 1, wherein weight values for partially constraining the intermediate area by blending vertex displacements in the physics simulation steps are determined by a function selected by a user.

8. The clothing simulation method of claim 7, wherein the function is selected from a predetermined number of preset functions displayed to the user on a graphical user interface.

9. The clothing simulation method of claim 7, wherein the blending is performed by interpolation.

10. The clothing simulation method of claim 9, wherein weight values for interpolating in the intermediate area are adjusted to a value between 0 and 1 according to a weight function.

11. The clothing simulation method of claim 1, wherein the one or more activation areas cover a pattern including the one or more selected points or areas and another pattern adjacent to the pattern.

12. The clothing simulation method of claim 1, wherein the one or more activation areas cover a pattern including the one or more selected points or areas and another pattern in a layer different from the pattern.

13. The clothing simulation method of claim 1, further comprising displaying a pinching interface using which the motion or displacement is received from a user.

14. The clothing simulation method of claim 13, wherein the pinching interface displaces the one or more selected points or areas in a direction corresponding to a user input.

15. The clothing simulation method of claim 1, further comprising displaying a gizmo interface using which the motion or displacement is received from a user.

16. The clothing simulation method of claim 1, wherein the one or more activation areas include a portion visually displaying weight values for blending.

17. The clothing simulation method of claim 1, wherein the one or more activation areas cover a layer of a pattern when the pattern is multi-layered.

18. The clothing simulation method of claim 1, wherein at least a part of one or more regions external to the activation areas is propagated with deformation according to the motion or the displacement in subsequent physics simulation steps after the one or more physics simulation steps.

19. A non-transitory computer-readable storage medium storing instructions thereon, the instructions when executed by one or more processors cause the one or more processors to:
receive selection of one or more points or areas of clothing;
receive a motion or a displacement associated with the one or more points or areas;
determine one or more activation areas including the one or more selected points or areas and an intermediate area around the one or more selected points or areas, the one or more selected points or areas constrained by the received motion or the displacement in one or more physics simulation steps, and the intermediate area partially constrained by the motion or the displacement in the one or more physics simulation steps;
receive the motion or the displacement of the one or more selected points or areas; and
simulate the clothing with the one or more selected points or areas constrained according to the received motion or displacement in the physics simulation steps, and the intermediate area partially constrained according to the received motion or displacement in the physics simulation steps.

20. An electronic device comprising:
memory storing instructions,
an output interface displaying a user interface; and
one or more processors, wherein the instructions, when performed by the one or more processors, cause the electronic device to:
receive selection of one or more points or areas of clothing;
receive a motion or a displacement associated with the one or more points or areas;
determine one or more activation areas including the one or more selected points or areas and an intermediate area around the one or more selected points or areas, the one or more selected points or areas constrained by the received motion or the displacement in one or more physics simulation steps, and the intermediate area partially constrained by the motion or the displacement in the one or more physics simulation steps;
receive the motion or the displacement of the one or more selected points or areas; and
simulate the clothing with the one or more selected points or areas constrained according to the received motion or displacement in the physics simulation steps, and the intermediate area partially constrained according to the received motion or displacement in the physics simulation steps.
